(19) United States
(12) Patent Application Publication
(10) Pub. No.: US 2008/0096385 A1
(43) Pub. Date: Apr. 24, 2008

(54) SLURRY COMPOSITION FOR FORMING TUNGSTEN PATTERN AND METHOD FOR MANUFACTURING SEMICONDUCTOR DEVICE USING THE SAME

(75) Inventors: Seok Ju Kim, Gongju-si (KR); Hyu Bum Park, Chochiwon-eup (KR); Ki Hong Yang, Seongnam-si (KR); Gyu An Jin, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignees: Hynix Semiconductor Inc., Icheon-si (KR); Techno Semichem Co., Ltd., Seongnam-si (KR)

(21) Appl. No.: 11/862,443

(22) Filed: Sep. 27, 2007

(30) Foreign Application Priority Data
Sep. 27, 2006 (KR) 10-2006-0094347
Sep. 20, 2007 (KR) 10-2007-0096133

(51) Int. Cl. H01L 21/4763; C09K 13/00; C09K 13/02

(52) U.S. Cl. 438/653; 252/79.1; 252/79.5; 257/E21.495

(57) ABSTRACT

A method for manufacturing a semiconductor device with a slurry composition for forming a tungsten pattern. The method comprises: forming a trench in an insulating film formed on a substrate; depositing a tungsten film over the insulating film including the trench; first polishing a tungsten film with a first slurry for polishing metal to expose the insulating film, the polishing selectivity ratio of the first slurry onto tungsten/insulating film being range from 30 to 100; and second polishing the insulating film and the tungsten film with a second slurry, the polishing selectivity ratio of the second slurry onto insulating film/tungsten being range from 3 to 500. The method reduces a thickness difference of tungsten patterns, thereby improving a production yield of semiconductor devices.

### CROSS-REFERENCES TO RELATED APPLICATIONS

The present application claims priority to Korean patent application number 10-2006-0094347 and 10-2007-0096133, respectively filed on Sep. 27, 2006 and Sep. 20, 2007, which are incorporated by references in their entireties.

### BACKGROUND OF THE INVENTION

The present invention relates to a slurry composition used in forming a tungsten pattern, and a method for manufacturing a semiconductor device using the same.

As a semiconductor device becomes smaller and the number of metal lines becomes larger, the irregularity of each layer is transferred to the next layer, so that the highest layer from the point of the substrate has the most irregularity. The irregularity affects the next step that makes it difficult to obtain a desired shape.

In order to improve the yield of semiconductor devices, it is necessary to perform a planarization process on the irregular surface to minimize line resistance deviation in a semiconductor manufacturing process.

The planarization process includes the process depositing Spin On Glass (SOG) material having a high deposition uniformity; the process depositing Boro-Phospho Silicate Glass (BPSG) film and performing a reflow process; or the process performing an etch-back or a Chemical Mechanical Polishing (CMP) after forming a film. The CMP method has been widely used because the CMP method provides a global planarization process while the reflow process or the etch-back process has difficulty planarizing a large area.

The CMP method is performed with polishing slurry applied where a polishing pad contacts directly with a substrate. That is, the surface of the substrate is mechanically and chemically planarized by the polishing pad coated with the slurry. The slurry composition differentiates depending on polishing characteristics such as polishing speed, defects in the polishing surface, dishing, and erosion.

The CMP method has been used to planarize dielectric materials such as silicon oxide film and silicon nitride film, and also metal films such as tungsten (W), aluminum (Al) and copper (Cu).

As a composition for polishing metal films including tungsten, Korean Patent Application No. 2002-7009918 (WO 2001/57150) has disclosed a selective tungsten polishing slurry containing an alumina abrasive, which causes a low diffusion of the composition. In order to prevent the low diffusion, a polishing composition containing a silanol has been provided. Korean Patent Application No. 2004-7011428 (WO 2003/62337) has disclosed a tungsten polishing slurry including a first oxidizer including hydrogen peroxide, ferrocyanide and dichromate and a second oxidizer including bromate, chlorate and iodate to reduce a static etching speed. When the idoate is used, alumina (abrasive) particles are required to remove a tungsten oxide which causes scratches. Korean Patent Application No. 1998-0702220 (WO 1998/04646) has disclosed a chemical mechanical polishing slurry including a selectively oxidizing and reducing compound of 0.5˜20 parts by weight, based on 100 parts by weight of the slurry to produce a differential in the removal of a metal and a dielectric material.

However, the slurry for polishing tungsten causes an erosion in a region where tungsten patterns are densely disposed. That is, an insulating film such as a nitride film 3 and an oxide film 5 is deposited over an underlying layer 1 of a semiconductor substrate. A pattern (not shown) for forming a metal line is formed on the insulating film. A Ti diffusion barrier film and a tungsten film 7 are sequentially formed. When a semiconductor substrate is polished with a slurry having a high polishing speed for tungsten, dishing 9 and erosion occurs over the substrate from a difference of polishing speeds between the tungsten film and the insulating film (see FIG. 1). The dishing represents a phenomenon where the inside of the pattern is over-polished causing it to be sunken-in (i.e., concave). The erosion represents a generation of a step difference between the metal line pattern region and the insulating film region which does not include metal line patterns.

### SUMMARY OF THE INVENTION

Various embodiments of the present invention relate to a slurry composition for forming a tungsten pattern to prevent dishing and erosion generated when a tungsten film over an insulating film is polished in a damascene process for forming a tungsten pattern, and a method for manufacturing a semiconductor device which includes a two-step polishing process with the slurry composition.

Various embodiments of the present invention also relate to a slurry composition for forming a tungsten pattern, which has a high polishing selectivity ratio between the insulating film and the tungsten film and an excellent diffusion characteristic, thereby reducing scratches and preventing dishing and erosion.

According to an embodiment of the present invention, a slurry composition comprises a silica abrasive, and at least one an additive of an amino acid type complexing agent and an alcohol organic compound. A polishing selectivity ratio of the slurry is insulating film:tungsten=3˜500:1.

Various embodiments of the present invention are directed at providing a method for manufacturing a semiconductor device, which comprises a first polishing step with a slurry having a rapid polishing speed to a tungsten film, and a second polishing step with a reverse selective slurry having a rapid polishing speed to an insulating film.

According to an embodiment of the present invention, a method for manufacturing a semiconductor device comprises: forming a trench in an insulating film formed on a substrate; depositing a tungsten film over the insulating film including the trench; first polishing a tungsten film with a first slurry for polishing metal to expose the insulating film, the polishing selectivity ratio of the first slurry onto tungsten/insulating film being range from 30 to 100; and second polishing the exposed insulating film and the tungsten film with the second slurry for planarization, the polishing selectivity ratio of the second slurry onto insulating film/tungsten being range from 3 to 500. A tungsten pattern comprises a tungsten plug and a tungsten wiring.

Since the first polishing process is performed with a slurry having a slow polishing selectivity ratio to an insulating film but a faster polishing selectivity ratio to a tungsten film, the polishing process can be instantly stopped when the insulating film is exposed. However, a dishing and erosions are generated over the tungsten 20 pattern. The second polishing process is subsequently performed with the reverse selective slurry having a high polishing speed to the insulating film so as to remove the dishing and the erosion generated in the first polishing process, thereby planarizing the substrate.

### BRIEF DESCRIPTION OF THE DRAWINGS

FIG. 1 is a cross-sectional diagram illustrating a tungsten pattern formed by a conventional method.

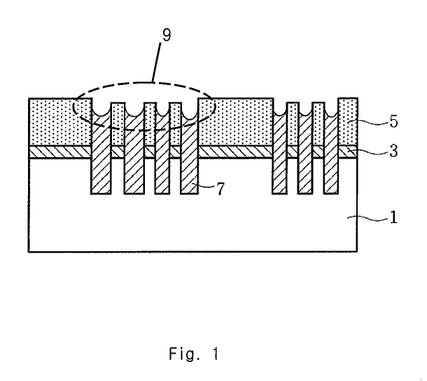

FIGS. 2a through 2c are diagrams illustrating a two-step polishing method according to an embodiment of the present invention.

FIG. 3 is a Transmission Electron Microscope (TEM) photograph of the tungsten pattern according to an embodiment of the present invention.

FIG. 4 is a graph illustrating a dishing decrease during the two-step polishing method according to an embodiment of the present invention.

FIG. 5a is a graph illustrating an erosion decrease of the top portion of the tungsten pattern depending on a two-step polishing time.

FIG. 5b is a graph illustrating an erosion decrease of a top portion of a tungsten plug pattern depending on a two-step polishing time.

### DETAILED DESCRIPTION OF THE SPECIFIC EMBODIMENT

The present invention will be described in detail with reference to the accompanying drawings.

There is provided a slurry composition used in the process for forming a tungsten pattern that comprises a silica abrasive, and at least one additive of an amino acid type complexing agent and an alcohol organic compound instead of an oxidizer or a catalyst. The slurry may further comprise a residual distilled water or ultra-pure water.

The silica abrasive includes a fumed silica and a colloidal silica. The fumed silica has a specific surface area ranging from 50 to 400 m²/g (e.g., 70 to 200 m²/g). The fumed silica in the slurry has a secondary average particle size ranging from 70 to 250 nm (e.g., 100 to 170 nm). A scratch can be generated when the silica particle size exceeds 250 nm, and a polishing speed is degraded when the silica particle size is less than 70 nm.

The colloidal silica has a primary particle size ranging from 10 to 200 nm (e.g., 30 to 120 nm). A scratch can be generated when the silica particle size exceeds 200 nm, and a polishing speed is degraded when the silica particle size is less than 10 nm.

The fumed silica abrasive can be present in an amount ranging from 1 to 20 parts by weight (e.g., 2 to 12 parts by weight), based on 100 parts by weight of the slurry. The colloidal silica abrasive can be present in an amount ranging from 1 to 20 parts by weight (e.g., 5 to 15 parts by weight) based on 100 parts by weight of the slurry. A polishing speed is degraded when the abrasive is present in the amount less than 1 parts by weight, and a scratch can be generated when the abrasive is present in an amount more than 20 parts by weight.

The complexing agent stabilizes a WOx (tungsten oxide) type anion to prevent re-adhesion on the substrate. The amino acid type complexing agent is selected from the group consisting of glycine, alanine, valine, aspartic acid, glutamic acid, and combinations thereof.

The complexing agent can be present in an amount ranging from 0.001 to 1.0 parts by weight (e.g., 0.005 to 0.2 parts by weight) based on 100 parts by weight of the slurry. It is difficult to prevent re-adhesion of the WOx type anion when the complexing agent is present in an amount less than 0.001 parts by weight, and the dispersibility of the slurry is degraded when the complexing agent is present in an amount more than 1.0 parts by weight.

The alcohol organic compound inhibits adhesion of polishing particles on the polished surface and generation of scratches, and facilitates wetting of the fumed silica to improve the dispersibility of the slurry. As the alcohol organic compound, a compound including one or more hydroxyl groups (OH) in a linear or branched carbon chain can be used. The alcohol organic compound is selected from the group consisting of methanol, ethanol, propanol, butanol, pentanol, ethyleneglycol, propyleneglycol, butandiol, glycerin, threitol, xylitol, sorbitol, and combinations thereof.

The alcohol organic compound can be present in an amount ranging from 0.005 to 3.0 parts by weight (e.g., 0.01 to 0.5 parts by weight) based on 100 parts by weight of the slurry. It is difficult to control scratches generated by the slurry when the alcohol organic compound is present in an amount less than 0.005 parts by weight, and the dispersibility of the slurry is degraded when the alcohol organic compound is present in an amount more than 3.0 parts by weight.

A pH of the slurry is controlled to obtain a dispersion stability and a proper polishing speed depending on abrasives. In the case of the slurry comprising of fumed silica abrasive, the slurry has a basic (alkaline) pH ranging from 8 to 12 (e.g., 9 to 12). In case of the slurry comprising the colloidal silica abrasive, the slurry can be a base or acid with a pH ranging from 1 to 12 (e.g., 1 to 4 or 9 to 12). A pH controller such as an inorganic or organic acid, a metal hydroxide and an amine base can be used to control the pH of the slurry, for example HNO₃ or KOH.

The slurry has a polishing selectivity ratio of insulating film to tungsten of 3˜500:1 (e.g., 3˜100:1 or 3˜70:1 or 3˜20:1). A polishing speed of the slurry on the insulating film ranges from 100 to 5,000 Å/min (e.g., 300 to 3,000 Å/min). When the polishing selectivity ratio to the insulating film is less than 3, it is difficult to remove erosion formed over a substrate and to obtain a uniformly polished substrate because a polishing speed difference, which depends on a density of a pattern, is increased. However, when the polishing selectivity ratio to the insulating film is more than 500, it is difficult to control the polishing time. Although the polishing speed condition is satisfied, the process time becomes ineffectively longer when the polishing speed to the insulating film is less than 100 Å/min, thereby increasing cost, and it is difficult to select a proper polishing end point so that the insulating film is over-polished when the polishing speed to the insulating film is more than 5,000 Å/min.

The slurry has a small number of macro-particles due to the excellent dispersibility so as to reduce the generation of scratches in the polishing process, thereby improving yield rate.

According to an embodiment of the present invention, a method for manufacturing a semiconductor device comprises: forming a trench for forming a metal line over an insulating film formed on a substrate; depositing a tungsten film over the insulating film including the trench; polishing a tungsten film with a first slurry whose polishing selectivity ratio of tungsten/insulating film is more than 30 to expose the insulating film; and polishing the exposed insulating film and the tungsten film with the disclosed slurry for forming a tungsten pattern whose polishing selectivity ratio of insulating film/tungsten is more than 3.

A tungsten pattern comprises a tungsten plug and a tungsten wiring.

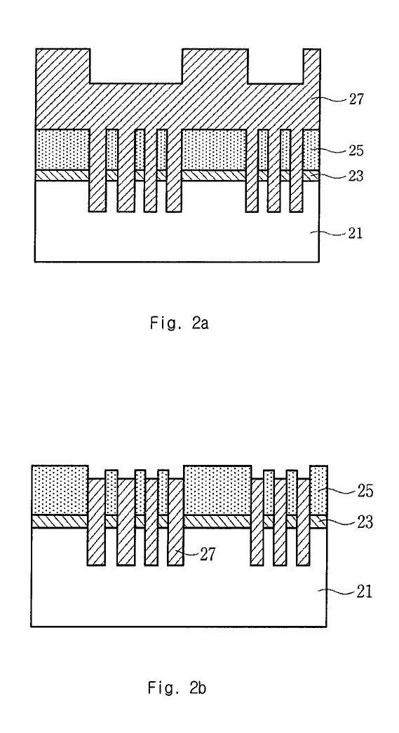

FIGS. 2a through 2c illustrates a method for manufacturing a semiconductor device comprising the two step polishing process according to an embodiment of the present invention.

Referring to FIG. 2a, a first insulating film 23 and a second insulating film 25 are sequentially deposited over an underlying layer 21 of a substrate (not shown). The first insulating film, the second insulating film and the underlying layer are etched to form a trench (not shown) for forming a tungsten pattern. A tungsten film 27 is deposited over an oxide film including the trench.

As an example, the first insulating film includes a nitride film, and the second insulating film includes a silicon oxide film. The silicon oxide film is formed by a Plasma Enhanced Chemical Vapor Deposition (PECVD) method and a High Density Plasma Chemical Vapor Deposition (HDP CVD) method.

Before the tungsten film 27 is deposited, a diffusion barrier film (not shown) including a Ti film or a Ti/TiN film may be further formed over the second insulating film 25.

FIG. 2b illustrates a resulting structure obtained by first polishing the tungsten film 27 until the second insulating film 25 is exposed.

A first slurry used in the first polishing process has been widely used. The conventional first slurry has a polishing selectivity ratio of tungsten to insulating film of 30˜100:1. The first slurry has a tungsten polishing speed ranging from 2,000 to 10,000 Å/min.

Only when the polishing selectivity ratio of tungsten/insulating film of the first slurry is more than 30 can the first polishing process to expose the insulation film be stopped. When the tungsten polishing speed is less than 2,000 Å/min, the process time becomes ineffectively longer, thereby increasing manufacturing time and cost. When the tungsten polishing speed is more than 10,000 Å/min, erosion occurs frequently over the substrate and it is difficult to perform a stable polishing process. The end point of the first polishing step may be detected by an end point detection (EPD) system which includes a motor current EPD system.

As the first slurry has a high tungsten polishing speed, an acidic slurry of pH 2 (produced by Cabot corp., Model No. SSW-2000) includes a fumed silica abrasive, a hydrogen peroxide as an oxidizer, and an iron nitrate as a catalyst. The slurry has a tungsten polishing speed of about 4,000 Å/min, and a polishing selectivity ratio of tungsten to insulating film of 70:1.

FIG. 2c illustrates a resulting structure obtained by polishing (second polishing step) the exposed second insulating film 25 and the tungsten film 27 with the disclosed slurry to remove the dishing and erosion generated in the first polishing step. The disclosed slurry is a reverse-selective tungsten slurry having a polishing selectivity ratio of insulating film to tungsten of 3˜500:1. The disclosed slurry is used as a second slurry.

The disclosed slurry has a pH ranging from 9.5 to 11.5 and includes a fumed silica abrasive of 2˜12 parts by weight having a particle size ranging from 100 to 170 nm, an alcohol organic compound of 0.01˜0.5 parts by weight, and a complexing agent of 0.005˜0.2 parts by weight. Otherwise, the disclosed slurry has a pH ranging from 1 to 4 or from 9 to 12 and includes a 5˜15 parts by weight colloidal silica abrasive having a particle size ranging from 30 to 120 nm, a 0.01˜0.5 parts by weight alcohol organic compound, and a 0.005˜0.2 parts by weight complexing agent.

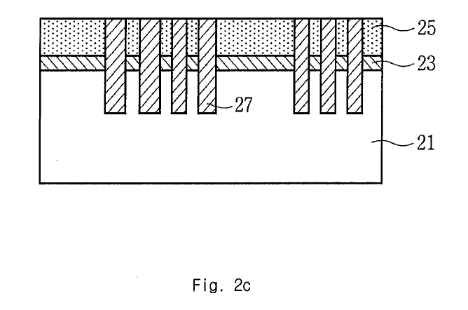

As a result, a tungsten pattern having an excellent planar surface can be formed (see FIG. 3).

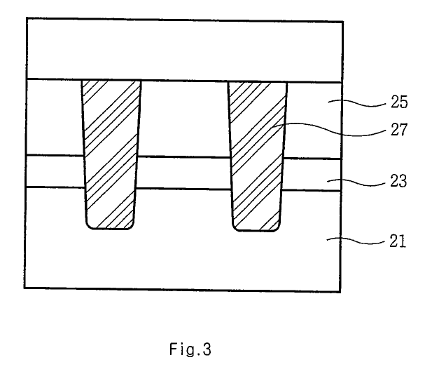

The first polishing process is performed with the slurry having a high polishing speed to tungsten and a low polishing speed to the insulating film. As a result, the first polishing process is stopped when the insulating film is exposed. The local step difference such as dishing (or erosion) generated on the surface of the tungsten pattern and the exposed insulating film can be effectively removed by a second polishing process with the disclosed slurry for forming a tungsten pattern, thereby improving uniformity of the substrate (see FIG. 4).

That is, to planarize a substrate a second polishing method performed with slurry of the present embodiment removes dishing and erosion without producing scratches. Moreover, the second polishing method reduces a thickness difference between tungsten patterns, thereby decreasing a resistance difference between tungsten patterns. As a result, a subsequent process margin increases so that yield rate of the semiconductor device is improved.

A wafer used to observe a polishing characteristic of the present embodiment is a blanket wafer produced by Hynix Semiconductor Inc. that includes a chemical vapor deposition tungsten film, a plasma-enhanced chemical vapor deposition silicon oxide film (PETEOS) and a high density plasma (HDP) silicon oxide film.

A wafer used to observe improvements in dishing and erosion is a 5-4 pattern piece wafer produced by Hynix Semiconductor Inc. where a line pattern is formed by an etching process on a PETEOS film, and then a Ti diffusion barrier film and a tungsten film are deposited at 3000 Å. The degree of dishing and erosion is measured using Alpha step Equipment from KLA-Tencor.

A Unipla 211 from DOOSAN DND Co. and a Poli500 CE from G&P Technology Co. are used as polishing equipment. When DOOSAN DND equipment is used, an IC1000 pad from Rohm & Haas Co. is used as a polishing pad. A polishing process for planarization of a wafer is performed with a slurry supply of 200 mL/min, under a substrate pressure of 3 psi and a retainer ring pressure of 6 psi, at a spindle rotation number of 60 rpm. When G&P Technology equipment is used, a IC1400 pad from Rohm & Haas Co. is used as a polishing pad. And, a polishing process of pattern piece wafer is performed with a slurry supply of 200 mL/min, under a polishing pressure of 200 g/cm², at a Table/Head speed of 80/80 rpm.

The thickness of the tungsten film is obtained by a surface resistance measuring instrument having a four point probe produced by Changmin Tech. Co. to convert the surface resistance into a thickness. The thickness of PETEOS and HDP films is measured using a Spectra Thick 4000 from Kmac Co.

As the first slurry used in the first polishing process, a slurry of Cabot Co. (SSW-2000) is used which includes a fumed silica abrasive, a hydrogen peroxide and an iron nitrate as a catalyst, and has a polishing selectivity ratio of tungsten to insulating film of 70:1 and a tungsten polishing speed of 4000 Å/min.

The disclosed slurry includes a colloidal silica or fumed silica abrasive, glycerin and glycine selectively. The colloidal silica is used by diluting a product of ACEHITECH Co. (the first particle size: 45 nm and 80 nm), and the fumed silica is used by dispersing a product of DEGUSA Co. (the first particle size: 20 nm).

### Example 1

### Preparation of a Slurry Composition

The fumed silica abrasive (the first particle size: 20 nm) was added and stirred into ultra-pure water according to Table 1, and then the pH of the slurry is changed to obtain a slurry of the present embodiment. The fumed silica in the slurry has a secondary average particle size of 140 nm. The planarization wafer (produced by Hynix Semiconductor Inc.) was polished with the slurry, thereby obtaining a polishing selectivity ratio of the insulating film (PETEOS) to tungsten as shown in Table 1. The polishing selectivity ratio was estimated using an Unipla 211 produced by DOOSAN DND Co.

TABLE 1

| silica | | | | polishing |
|---|---|---|---|---|
| content | | | tungsten (W) | selectivity |
| (parts by | | PETEOS polishing | polishing speed | ratio |
| weight) | pH | speed (Å/min) | (Å/min) | (PETEOS/W) |
| 5.7 | 2 | 115 | 15 | 8 |
| 5.7 | 10 | 747 | 12 | 62 |
| 5.7 | 10.9 | 875 | 13 | 67 |

The silica content is based on 100 parts by weight of the slurry.

Referring to Table 1, the selectivity (PETEOS/W) shows more than 3, and the fumed silica has the higher polishing selectivity difference in the basic slurry than in the acidic slurry. As a result, the basic slurry comprising the fumed silica can be used as disclosed slurry for forming a tungsten pattern.

After the planarization wafer was polished with a slurry with a pH of 10.9 and a fumed silica content of 5.7 parts by weight, there was no defects such as a dishing and erosion as can be seen in a TEM analysis result (see FIG. 3).

### Example 2

### Preparation of a Slurry Composition and a Polishing Selectivity Ratio Thereof

The colloidal silica abrasive and methanol (0.05 parts by weight, based on 100 parts by weight of the slurry) as an alcohol organic compound were added and stirred into ultra-pure water according to the rate of Table 2, and then the pH of the slurry is changed to obtain a slurry of the present embodiment. The planarization wafer (produced by Hynix Semiconductor Inc.) was polished with the slurry, thereby obtaining a polishing selectivity ratio of insulating film (PETEOS) to tungsten as shown in Table 2. The polishing selectivity ratio was estimated using a Poli500 CE produced by G&P Technology Co.

TABLE 2

| | silica | | PETEOS | tungsten (W) | polishing |
|---|---|---|---|---|---|
| particle | content | | polishing | polishing | selectivity |
| size | (parts by | | speed | speed | ratio |
| (nm) | weight) | pH | (Å/min) | (Å/min) | (PETEOS/W) |
| 45 | 10 | 2.3 | 1264 | 45 | 28 |
| | 10 | 10.5 | 1535 | 30 | 50 |
| 80 | 10 | 2.3 | 1611 | 60 | 27 |
| | 10 | 10.5 | 2920 | 44 | 67 |

The silica content is based on 100 parts by weight of the slurry.

Table 2 shows that the slurry comprising of the colloidal silica represents a polishing selectivity ratio of more than 3 for both acid and base conditions.

### Example 3

### Preparation of a Slurry Composition and a Polishing Selectivity Ratio Thereof

The fumed silica abrasive (the first particle size: 20 nm) and glycine (0.04 parts by weight, based on 100 parts by weight of the slurry) as a complexing agent were added and stirred into ultra-pure water according to the rate of Table 3, and then the pH of the slurry is changed to obtain a slurry of the present embodiment. The fumed silica in the slurry has a secondary average particle size of 140 nm. The planarization wafer (produced by Hynix Semiconductor Inc.) was polished with the slurry, thereby obtaining a polishing selectivity ratio of the insulating film (PETEOS) to tungsten as shown in Table 3. The polishing selectivity ratio was estimated using an Unipla 211 produced by DOOSAN DND Co.

TABLE 3

| silica | | | | tungsten | |
|---|---|---|---|---|---|
| content | Complexing | | PETEOS | (W) | polishing |
| (parts | agent | | polishing | polishing | selectivity |
| by | (parts by | | speed | speed | ratio |
| weight) | weight) | pH | (Å/min) | (Å/min) | (PETEOS/W) |
| 5.7 | 0.04 | 10.9 | 871 | 19 | 46 |
| 5.7 | | 11.9 | 875 | 13 | 67 |

The silica content is based on 100 parts by weight of the slurry.

### Example 4

### Preparation of a Slurry Composition and a Polishing Selectivity Ratio Thereof

The fumed silica abrasive (the first particle size: 20 nm), glycine as a complexing agent and an alcohol compound were added and stirred into ultra-pure water according to the rate of Table 4, to obtain a slurry of the present embodiment. The fumed silica in the slurry has a secondary average particle size of 140 nm. The planarization wafer (produced by Hynix Semiconductor Inc.) was polished with the slurry, thereby obtaining a polishing selectivity ratio of the insulating film (PETEOS) to tungsten as shown in Table 4. The polishing selectivity ratio was estimated using a Poli500 CE produced by G&P Technology Co.

TABLE 4

| silica | | | | | tungsten | polishing |
|---|---|---|---|---|---|---|
| content | Complexing | Alcohol | | PETEOS | (W) | selectivity |
| (parts | agent | compound | | polishing | polishing | ratio |
| by | (parts by | (parts by | | speed | speed | (PETEOS/ |
| weight) | weight) | weight) | pH | (Å/min) | (Å/min) | W) |
| 5.0 | glycine | glycerin | 10.9 | 765 | 16 | 48 |
| | 0.02 | 0.06 | | | | |
| 5.0 | | glycerin | 10.9 | 778 | 15 | 52 |
| | | 0.06 | | | | |
| | | methanol | | | | |
| | | 0.05 | | | | |

The contents of silica abrasive, complexing agent and alcohol compound are a based on 100 parts by weight of the slurry.

### Example 5

### Preparation of a Slurry Composition and a Polishing Selectivity Ratio Thereof

The fumed silica abrasive having the first particle size of 20 nm and glycine (0.02 parts by weight, based on 100 parts by weight of the slurry) as a complexing agent were added and stirred into ultra-pure water according to the rate of Table 5 to obtain a slurry of the present embodiment having a pH of 10.9. The fumed silica in the slurry has a secondary average particle size of 140 nm. The planarization wafer (produced by Hynix Semiconductor Inc.) was polished with the slurry, thereby obtaining a polishing selectivity ratio of the insulating film (PETEOS) to tungsten as shown in Table 5.

TABLE 5

| silica | | PETEOS | | | HDP | | |
|---|---|---|---|---|---|---|---|
| content | W | | | polishing | | | polishing |
| (parts | polishing | polishing | | selectivity | polishing | | selectivity |
| by | speed | speed | *NU | ratio | speed | *NU | ratio |
| weight) | (Å/min) | (Å/min) | (%) | (PETEOS/W) | (Å/min) | (%) | (PETEOS/W) |
| 3 | 15 | 401 | 7.8 | 27 | 405 | 4.4 | 27 |
| 4 | 14 | 604 | 5.6 | 43 | 555 | 4.0 | 40 |
| 5 | 14 | 795 | 5.7 | 57 | 708 | 5.5 | 51 |
| 6 | 13 | 921 | 6.0 | 71 | 825 | 7.9 | 63 |
| 11.3 | 13 | 1519 | 2.8 | 117 | 1327 | 3.1 | 102 |

*NU: non-uniformity [(standard deviation of polishing speed)/(average of polishing speed) × 100]
The silica abrasive content is based on 100 parts by weight of the slurry.

Table 5 shows that it is possible to control the polishing speed and polishing selectivity ratio of silicon oxide film by changing the amount of fumed silica in the slurry. The polishing speed of silicon oxide film ranges from 400 to 1600 Å/min.

### Example 6

### Test for Improving Dishing and Erosion of the Disclosed Slurry

The 5-4 pattern wafer (produced by Hynix Semiconductor Inc.) was first polished with a first slurry (produced by Cabot Co., Model No. SSW-2000) having a high polishing speed to tungsten, and 30% over-polished. The resulting structure was polished (second polishing step) with the slurry of Example 4 including 5.0 parts by weight fumed silica+0.06 parts by weight glycerin+0.02 parts by weight glycine.

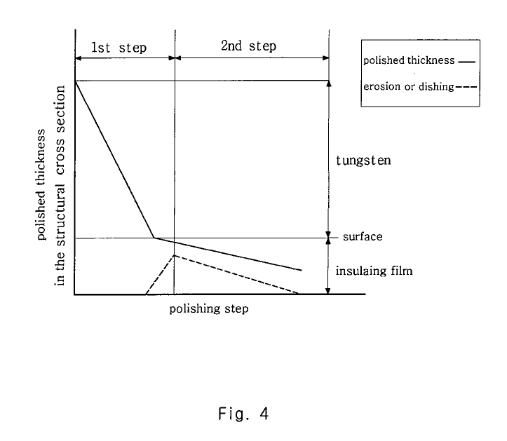

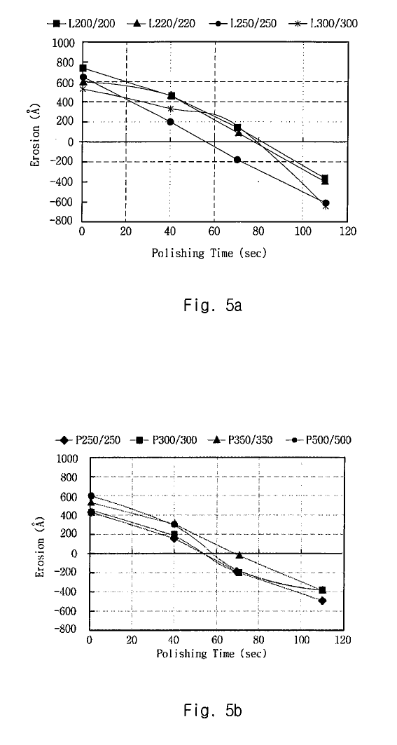

The dishing and erosion generated over the tungsten pattern depending on a polishing process time was tested using a Poli500 CE produced by G&P Technology Co., and test results are shown in FIGS. 5a and 5b.

FIG. 5a shows test results of the tungsten pattern. The pattern width of tungsten and oxide film is 200 nm, 220 nm, 250 nm and 300 nm. The erosion value measured after the first polishing process is represented as “0”. As a result, the erosion value is shown to decrease as the second polishing time increases. In about 70 seconds, the erosion is shown to be lowest.

FIG. 5b shows test results of the plug pattern. The pattern width of tungsten and oxide film is 250 nm, 300 nm, 350 nm and 500 nm. The erosion value measured after the first polishing process is represented as “0”. As a result, the erosion is shown to decrease as the second polishing time increases. At about 70 seconds, the erosion is shown to be lowest.

In the above two patterns, the erosion is shown to decrease as the second polishing time increases. Since the polishing speed of the silicon oxide film is faster than that of the tungsten film, the oxide film is rapidly removed and the erosion is decreased. As a result, the erosion generated from the first polishing process can be minimized if the proper polishing time is selected. In the present test, the proper polishing time is about 70 seconds although it is different depending on the kind of pattern.

As described above, according to an embodiment of the present invention, a slurry for forming a tungsten pattern reduces generation of scratches in a polishing process due to an excellent dispersibility. A two-step polishing method prevents generation of dishing and erosion, thereby facilitating a CMP process with an excellent planarization. The two-step polishing method reduces a thickness difference and a resistance difference of tungsten patterns to increase a process margin, thereby improving a production yield of semiconductor devices.

The above embodiments of the present invention are illustrative and not limitative. Various alternatives and equivalents are possible. The invention is not limited by the lithography steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A slurry composition for forming a tungsten pattern on a substrate using a chemical mechanical polishing process, the composition comprising:
a silica abrasive; and
at least one additive of a complexing agent and an alcohol organic compound.

2. The slurry composition according to claim 1, wherein the silica abrasive includes a fumed silica abrasive or a colloidal silica abrasive.

3. The slurry composition according to claim 2, wherein the fumed silica abrasive has a secondary average particle size ranging from 70 to 250 nm.

4. The slurry composition according to claim 2, wherein the colloidal silica abrasive has a primary particle size ranging from 10 to 200 nm.

5. The slurry composition according to claim 1, wherein the abrasive is present in an amount from 1 to 20 parts by weight, based on 100 parts by weight of the slurry composition.

6. The slurry composition according to claim 1, wherein the complexing agent is selected from the group consisting of glycine, alanine, valine, aspartic acid, glutamic acid, and combinations thereof,
wherein the complexing agent is used to stabilize a tungsten oxide type anion to prevent re-adhesion of tungsten removed by the chemical mechanical polishing process.

7. The slurry composition according to claim 1, wherein the complexing agent is present in an amount from 0.001 to no more than 1 parts by weight, based on 100 parts by weight of the slurry composition.

8. The slurry composition according to claim 1, wherein the alcohol organic compound is selected from the group consisting of methanol, ethanol, propanol, butanol, pentanol, ethyleneglycol, propyleneglycol, butandiol, glycerin, threitol, xylitol, sorbitol, and combinations thereof,
wherein the alcohol organic compound is present in a sufficient amount to control scratches on the tungsten pattern by the slurry and no more than a given amount to prevent the dispersibility of the slurry composition from being degraded.

9. The slurry composition according to claim 1, wherein the alcohol organic compound is present in an amount from 0.005 to no more than 3 parts by weight, based on 100 parts by weight of the slurry composition.

10. The slurry composition according to claim 2, wherein the slurry including the fumed silica abrasive has a pH ranging from 8 to 12.

11. The slurry composition according to claim 2, wherein the slurry including the colloidal silica abrasive has a pH ranging from 1 to 12.

12. The slurry composition according to claim 11, wherein a pH of the slurry ranges from 1 to 4 or from 9 to 12.

13. The slurry composition according to claim 1, wherein the slurry further comprises a pH control agent.

14. The slurry composition according to claim 13, wherein pH control agent includes an inorganic compound, an organic compound, a metal hydroxide and an amine base.

15. The slurry composition according to 13, wherein the pH control agent includes HNO₃ and KOH.

16. The slurry composition according to 1, wherein the slurry has a polishing selectivity ratio of insulating film:tungsten=3˜500:1.

17. The slurry composition according to claim 16, wherein the slurry has a polishing selectivity ratio of insulating film:tungsten=3˜100:1.

18. The slurry composition according to claim 17, wherein the slurry has a polishing selectivity ratio of insulating film:tungsten=3˜70:1.

19. The slurry composition according to claim 18, wherein the slurry has a polishing selectivity ratio of insulating film:tungsten=3˜20:1.

20. The slurry composition according to claim 16, wherein a polishing speed of the slurry to the insulating film ranges from 300 to 3000 Å/min.

21. A method for manufacturing a semiconductor device, the method comprising:
forming a trench for forming a tungsten pattern in an insulating film formed over a substrate;
depositing a tungsten film over the insulating film including the trench, the trench being filled with the tungsten film;
polishing a tungsten film with a slurry for polishing metal to expose the insulating film, the polishing selectivity ratio of the slurry for polishing metal onto tungsten/insulating film being range from 30 to 100; and
polishing the exposed insulating film and the tungsten film with a slurry of claim 1 for planarization.

22. The method according to claim 21, further comprising forming a diffusion barrier film over the insulating film before depositing a tungsten film.

23. The method according to claim 21, wherein the first slurry has a polishing speed of the tungsten ranges from 2,000 to 10,000 Å/min.

24. The method according to claim 21, wherein the first slurry includes a fumed silica abrasive, a hydrogen peroxide and an iron nitrate as a catalyst.

25. A method for manufacturing a semiconductor device, the method comprising:
forming a trench in insulating film formed over a substrate;
depositing a tungsten film over the insulating film including the trench, the tungsten film filing the trench;
polishing a tungsten film with a first slurry to expose the insulating film, the polishing selectivity ratio of the first slurry onto tungsten/insulating film being range from 30 to 100; and
polishing the exposed insulating film and the tungsten film with a second slurry for planarization, the polishing selectivity ratio of the second slurry onto insulating film/tungsten being range from 3 to 500.
